(19) United States
(12) Patent Application Publication
(10) Pub. No.: US 2026/0089300 A1
(43) Pub. Date: Mar. 26, 2026

(54) WAFER BONDING DEVICE

(71) Applicant: Samsung Electronics Co., Ltd., Suwon-si (KR)

(72) Inventors: Shinji Ueyama, Yokohama (JP); Fumitaka Moroishi, Yokohama (JP); Takamasa Sugiura, Yokohama (JP); Masato Kajinami, Yokohama (JP)

(21) Appl. No.: 19/322,201

(22) Filed: Sep. 8, 2025

(30) Foreign Application Priority Data
Sep. 25, 2024 (JP) 2024-166051
Dec. 27, 2024 (KR) 10-2024-0199326

(51) Int. Cl. H04N 13/243; H01L 21/67; H01L 21/683; H04N 13/254; H04N 13/296; H04N 23/11; H04N 23/56; H04N 23/74

(52) U.S. Cl. CPC H04N 13/243; H04N 13/254; H04N 13/296; H04N 23/11; H04N 23/56; H04N 23/74; H10P 72/0438; H10P 72/78

(57) ABSTRACT

Provide is a wafer bonding device. The wafer bonding device includes a bonding unit including a first chuck and a second chuck that are arranged to face each other, a light source arranged on sides of the first chuck and the second chuck and configured to radiate light onto a region between the first chuck and the second chuck, a plurality of cameras arranged on an opposite side of the light source with the first chuck and the second chuck therebetween and configured to capture images of a region irradiated with the light emitted from the light source, and a 3D image generator configured to generate three-dimensional image data representing a bonding scene of a first wafer and a second wafer.

### CROSS-REFERENCE TO RELATED APPLICATIONS

This application is based on and claims priority under 35 U.S.C. § 119 to Korean Patent Application No. 10-2024-0199326, filed on Dec. 27, 2024, in the Korean Intellectual Property Office, and to Japanese Patent Application No. 2024-166051, filed on Sep. 25, 2024, in the Japan Patent Office, the disclosures of which are incorporated by reference herein in their entireties.

### BACKGROUND

Aspects of the inventive concept provide a wafer bonding device.

A wafer bonding technique is crucial for achieving three-dimensional mounting of semiconductor devices. To prevent the generation of voids between wafers, bonding two wafers is performed by making the wafers contact each other after pressing the central portions of the wafers from the rear surfaces thereof to bend the same. Presence of voids between bonded wafers is inspected using an IR camera or other components in a testing device.

### SUMMARY

Aspects of the inventive concept provide a wafer bonding device with improved reliability.

According to an aspect of the inventive concept, there is provided a wafer bonding device including a bonding unit including a first chuck and a second chuck that are arranged to face each other, a light source arranged on sides of the first chuck and the second chuck and configured to radiate light onto a region between the first chuck and the second chuck, a plurality of cameras arranged on an opposite side of the light source with the first chuck and the second chuck therebetween and configured to capture images of a region irradiated with the light emitted from the light source, and a 3D image generator configured to generate three-dimensional image data representing a bonding scene of a first wafer and a second wafer by three-dimensionally reconstructing image data that is obtained by capturing the images of the region by using the plurality of cameras during the bonding of the first wafer and the second wafer, wherein the bonding unit is configured to bond the first wafer to the second wafer while holding the first wafer and the second wafer in place by suction by using the first chuck and the second chuck and making the first wafer and the second wafer come close to each other in a state in which at least one of the first wafer and the second wafer is bent so that central portions of the first wafer and the second wafer contact each other.

According to another aspect of the inventive concept, there is provided a wafer bonding device including a bonding unit including a first chuck and a second chuck that are arranged to face each other, a light source arranged on sides of the first chuck and the second chuck and configured to radiate light onto a region between the first chuck and the second chuck, a plurality of cameras arranged on an opposite side of the light source with the first chuck and the second chuck therebetween and configured to capture images of a region irradiated with the light emitted from the light source, and a 3D image generator configured to generate three-dimensional image data representing a bonding scene of a first wafer and a second wafer by three-dimensionally reconstructing image data that is obtained by capturing the images of the region by using the plurality of cameras during the bonding of the first wafer and the second wafer to each other, wherein the bonding unit is configured to bond the first wafer to the second wafer while holding the first wafer and the second wafer in place by suction by using the first chuck and the second chuck and making the first wafer and the second wafer come close to each other in a state in which at least one of the first wafer and the second wafer is bent so that central portions of the first wafer and the second wafer contact each other, each of the plurality of cameras is configured to consecutively capture images of the region in a predetermined imaging cycle, the 3D image generator is further configured to generate pieces of the three-dimensional image data representing behaviors of the first wafer and the second wafer during the bonding of the first wafer and the second wafer, based on image data that is consecutive at predetermined time intervals, and the number of cameras is greater than the number of light sources.

According to another aspect of the inventive concept, there is provided a wafer bonding device including a bonding unit including a first chuck and a second chuck that are arranged to face each other, a light source arranged on sides of the first chuck and the second chuck and configured to radiate light onto a region between the first chuck and the second chuck, a plurality of cameras arranged on an opposite side of the light source with the first chuck and the second chuck therebetween and configured to capture images of a region irradiated with the light emitted from the light source, a 3D image generator configured to generate three-dimensional image data representing a bonding scene of a first wafer and a second wafer by three-dimensionally reconstructing image data that is obtained by capturing the images of the region by using the plurality of cameras during the bonding of the first wafer and the second wafer to each other, an infrared camera that emits infrared light, and a range sensor configured to detect a distance between the first chuck and the second chuck, wherein the bonding unit is configured to bond the first wafer to the second wafer while holding the first wafer and the second wafer in place by suction on the first chuck and the second chuck respectively and making the first wafer and the second wafer come close to each other in a state in which at least one of the first wafer and the second wafer is bent so that central portions of the first wafer and the second wafer contact each other first and then edge portions of the first wafer and the second wafer contact each other, each of the plurality of cameras is configured to consecutively capture images of the region in a predetermined imaging cycle, and the infrared camera is configured to capture an image of an alignment mark of each of the first wafer and the second wafer. The 3D image generator is further configured to generate pieces of the three-dimensional image data representing behaviors of the first wafer and the second wafer during the bonding of the first wafer and the second wafer, based on image data that is consecutive at predetermined time intervals, and the number of cameras is greater than the number of light sources.

### BRIEF DESCRIPTION OF THE DRAWINGS

Embodiments will be more clearly understood from the following detailed description taken in conjunction with the accompanying drawings in which:

FIG. 1 is a block diagram of a wafer bonding device according to an embodiment;

FIG. 2 is a cross-sectional view of a structure of a bonding unit and a measurement unit included in a wafer bonding device, according to an embodiment;

FIG. 3 is a plan view of a structure of a measurement unit included in a wafer bonding device, according to an embodiment;

FIG. 4 is a flowchart of a wafer bonding process of a wafer bonding device, according to an embodiment;

FIG. 5A illustrates an example in which a wafer bonding device bonds wafers, according to an embodiment;

FIG. 5B is a diagram showing a subsequent process of FIG. 5A;

FIG. 5C is a diagram showing a subsequent process of FIG. 5B;

FIG. 5D is a diagram showing a subsequent process of FIG. 5C;

FIG. 5E is a diagram showing a subsequent process of FIG. 5D; and

FIG. 6 illustrates an example of a captured image.

### DETAILED DESCRIPTION OF THE EMBODIMENTS

As the disclosure allows for various changes and numerous embodiments, particular embodiments will be shown in the drawings and described in detail in the written description. It is not intended to limit the present embodiments to specific embodiments. In addition, embodiments described below are only examples, and various modifications may be made to these embodiments.

The use of any and all examples, or illustrative language provided herein, is intended merely to better illuminate the inventive concept and does not pose a limitation on the scope of the invention unless otherwise claimed.

Unless otherwise specifically described, in the present specification, the vertical direction may be defined as a Z direction, and the first horizontal direction and the second horizontal direction may each be defined as a horizontal direction perpendicular to the Z direction. The first horizontal direction may be referred to as X direction, while the second horizontal direction may be referred to as Y direction. The vertical level may refer to a height or a level in the vertical direction Z. A horizontal length and a horizontal width may refer to a length in the horizontal direction (X and/or Y), and a vertical length may refer to a length in the vertical direction Z. In addition, a two-dimensional space stated in the present specification may be a dimension formed in the first horizontal direction and the second horizontal direction. For example, two-dimensional direction may be referred to simply as a horizontal direction. For example. The first horizontal direction X and the second horizontal direction may be perpendicular to each other.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Spatially relative terms, such as “vertical,” “horizontal,” “beneath,” “below,” “lower,” “above,” “upper,” “top,” “bottom,” “front,” “rear,” and the like, may be used herein for case of description to describe positional relationships, such as illustrated in the figures, for example. It will be understood that the spatially relative terms encompass different orientations of the device in addition to the orientation depicted in the figures.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

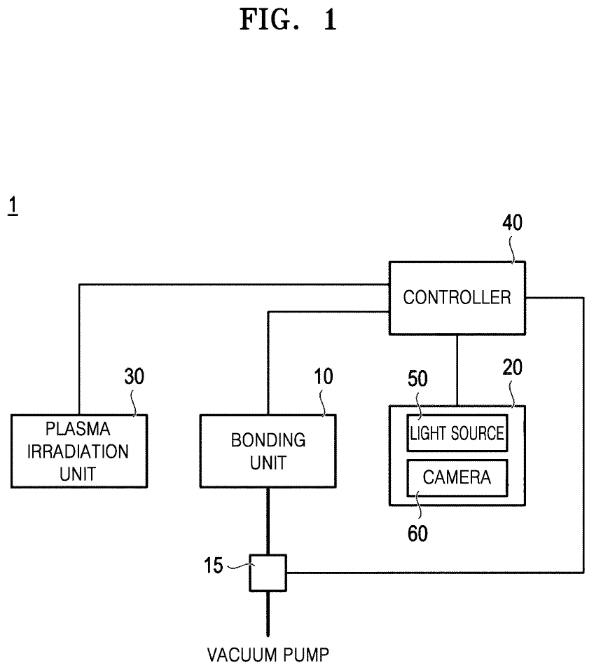

FIG. 1 is a block diagram of a wafer bonding device according to an embodiment.

As shown in FIG. 1, a wafer bonding device 1 includes a bonding unit 10, a measurement unit 20, a plasma radiation unit 30, and a controller 40.

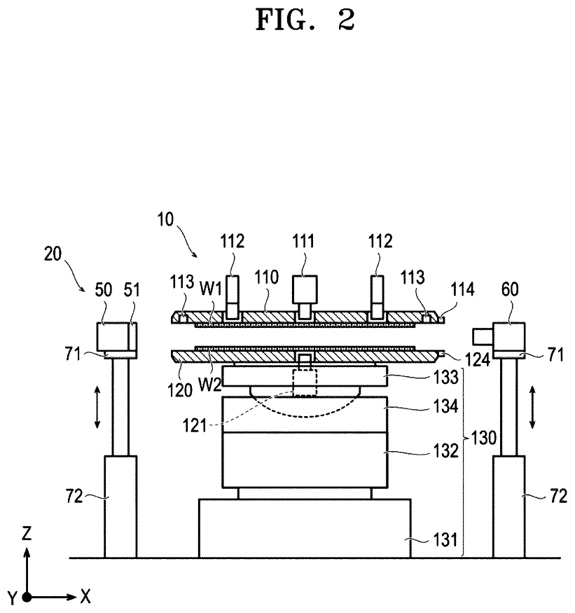

The bonding unit 10 bonds two wafers (a first wafer W1 and a second wafer W2 of FIG. 2) to each other. The bonding unit 10 is connected to an external vacuum pump through a control valve 15 and bonds the two wafers (the first wafer W1 and the second wafer W2 of FIG. 2) to each other while maintaining suction to hold the two wafers in place on respective chucks. The bonding unit 10 bonds the two wafers (the first wafer W1 and the second wafer W2 of FIG. 2) by making the two wafers come close to each other while each wafer is bent so that the central portions of the two wafers (the first wafer W1 and the second wafer W2 of FIG. 2) contact each other first and then, contact portion of the first wafer and the second wafer expand from the central portions to the edge portions of the first wafer and the second wafer.

The measurement unit 20 measures a bonding process of the wafers (the first wafer W1 and the second wafer W2 of FIG. 2). The measurement unit 20 includes a light source 50 and a camera 60 and radiates light onto a boundary region between the two wafers (the first wafer W1 and the second wafer W2 of FIG. 2) being bonded to each other, while capturing an image of the boundary region.

The plasma radiation unit 30 radiates plasma onto the two wafers (the first wafer W1 and the second wafer W2 of FIG. 2), e.g., onto the bonding surfaces of the two wafers, to activate the bonding surfaces thereof. The wafers irradiated with plasma by the plasma radiation unit 30 are transferred to the bonding unit 10 by a transfer robot (not shown).

The controller 40 controls the aforementioned units or performs various computational operations. The controller 40 is implemented as a computer and includes a Central Processing Unit (CPU), memory (e.g., Read-Only Memory (ROM) or Random Access Memory (RAM)), a storage unit (e.g., a Hard Disk Drive (HDD) or a Solid State Drive (SSD)), a display, and an input unit (a keyboard, etc.).

The storage unit of the controller 40 stores therein a program for controlling the operation of each unit, a program for three-dimensionally reconstructing image data that may be obtained by capturing images of the boundary region between the two wafers (the first wafer W1 and the second wafer W2 of FIG. 2) by using the camera 60, and a program (a trained model) for determining whether the bonding quality of the two wafers (the first wafer W1 and the second wafer W2 of FIG. 2) is acceptable. As the CPU executes the program for three-dimensionally reconstructing image data, the controller 40 in the present embodiment functions as a generator that generates three-dimensional image data by three-dimensionally reconstructing two-dimensional image data. In addition, the term “three-dimensional reconstruction” refers to a technique for restoring a three-dimensional model (three-dimensional image data) of a scene from two-dimensional image data obtained by capturing images of the scene from multiple points of view. For example, the generator may be a 3D image generator.

In addition, the wafer bonding device 1 may include components other than those described above or not include some of the aforementioned components. For example, the controller 40 may further include a Graphics Processing Unit (GPU) for performing three-dimensional reconstruction of image data. Alternatively, the wafer bonding device 1 may include a computer for three-dimensionally reconstructing the image data or determining the bonding quality of wafers, e.g., outside the controller 40. For example, the computer may be separated from the controller 40.

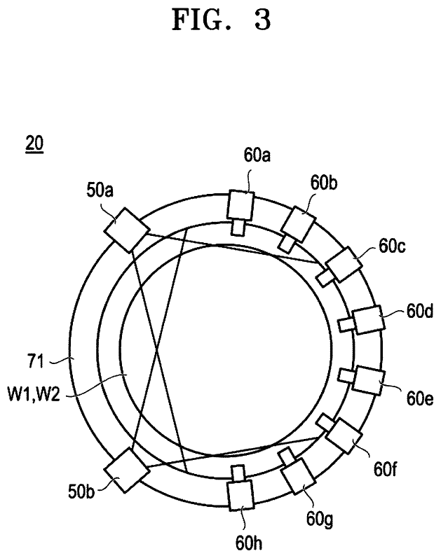

FIG. 2 is a cross-sectional view of a structure of a bonding unit and a measurement unit included in a wafer bonding device, according to an embodiment. FIG. 3 is a plan view of a structure of a measurement unit included in a wafer bonding device, according to an embodiment.

The bonding unit 10 includes a first chuck 110 and a second chuck 120, which are facing each other, and a driving unit 130 that changes locations of the first chuck 110 and the second chuck 120.

The first chuck 110 and the second chuck 120 respectively hold the first wafer W1 and the second wafer W2 in place by suction. The first chuck 110 and the second chuck 120 may include, for example, ceramic, and respectively hold the first wafer W1 and the second wafer W2 in place by suction by using negative pressure that is applied to suction grooves formed in the wafer holding surfaces of the first chuck 110 and the second chuck 120. The suction grooves may be independently formed in each of division regions, which are obtained/formed by dividing the wafer holding surfaces of the first chuck 110 and the second chuck 120, and the wafer bonding device 1 may adjust a suction retention force of the wafer holding surfaces of the first chuck 110 and the second chuck 120 independently for each division region.

The first wafer W1 and the second wafer W2 are wafers each having a circular shape in a plan view. The first wafer W1 and the second wafer W2 may each include silicon. Alternatively, the first wafer W1 and the second wafer W2 may each include a semiconductor element such as germanium (Ge) or a compound semiconductor such as silicon carbide (SiC), gallium arsenide (GaAs), indium arsenide (InAs), or indium phosphide (InP). Alternatively, the first wafer W1 and the second wafer W2 may each have a Silicon-on-Insulator (SOI) structure. In some embodiments, the first wafer W1 and the second wafer W2 may each include a conductive region, e.g., a well or a structure doped with impurities. The first wafer W1 and the second wafer W2 may also have various device isolation structures, such as a shallow trench isolation (STI) structure. In the present specification, it is assumed that the first wafer W1 and the second wafer W2 have a diameter of about 12 inches, and the case where silicon wafers are used is described. However, one of ordinary skill in the art would understand that the first wafer W1 and the second wafer W2 have a diameter that is less or greater than about 12 inches and include a material other than silicon.

A semiconductor device layer may be formed on each of active surfaces of the first wafer W1 and the second wafer W2. The semiconductor device layer may include an insulating layer and/or a conductive layer provided on each of the active surfaces of the first wafer W1 and the second wafer W2. In addition, the semiconductor device layer may include a semiconductor device and a metal interconnect structure. The semiconductor device of the semiconductor device layer may include or may be a memory device and/or a logic device.

The memory device may include or may be a volatile memory device or a non-volatile memory device. The volatile memory device may include, for example, existing volatile memory devices such as Dynamic Random Access Memory (DRAM), Static RAM (SRAM), Thyristor RAM (TRAM), Zero Capacitor RAM (ZRAM), or Twin Transistor RAM (TTRAM) and volatile memory devices that are currently under development. The non-volatile memory device may include, for example, existing non-volatile memory devices such as flash memory, Magnetic RAM (MRAM), Spin-Transfer Torque MRAM (STT-MRAM), Ferroelectric RAM (FRAM), Phase Change RAM (PRAM), Resistive RAM (RRAM), nanotube RRAM, polymer RAM, nano floating gate memory, holographic memory, molecular electronics memory, or insulator resistance change memory or non-volatile memory devices that are currently under development.

The logic device may be implemented as, for example, a microprocessor, a graphics processor, a signal processor, a network processor, an audio codec, a video codec, an application processor, or a system on chip, but is not limited thereto. The microprocessor may include, for example, a single core or multiple cores.

A first pressing member 111 and a second pressing member 121 that press the first wafer W1 and the second wafer W2 may be installed on the first chuck 110 and the second chuck 120, respectively. The first pressing member 111 and the second pressing member 121 press the central portions of the first wafer W1 and the second wafer W2 from the rear surfaces thereof through openings installed/formed in the first chuck 110 and the second chuck 120, respectively. Weight sensors for detecting contacts with the first wafer W1 and the second wafer W2 are installed at the ends of the first pressing member 111 and the second pressing member 121. For example, the first pressing member 111 and the second pressing member 121 may include metal and/or dielectric material.

In addition, the first chuck 110 is equipped with a plurality of infrared cameras 112 and a plurality of range sensors 113. Each infrared camera 112 may be, for example, an InGaAs camera, and configured to move (e.g., movable) in vertical and horizontal directions by a driving device that is not shown. The infrared camera 112 captures images of alignment marks of the first wafer W1 and the second wafer W2 while radiating infrared light from an infrared light source (not shown). The range sensor 113 may be, for example, a capacitive sensor, and may detect a distance between the wafer holding surface of the first chuck 110 and the wafer holding surface of the second chuck 120. The range sensor 113 is installed at a location on the edge portion of the first chuck 110, where the range sensor 113 does not overlap the first wafer W1. For example, the range sensor 113 may be a distance sensor and/or a proximity sensor.

In embodiments, the range sensor 113 may include or may be a confocal sensor. In this case, although not shown, the range sensor 113 may include a light source, a lens optical system including a plurality of lenses, a beam splitter, and a detector. For example, the light source may output light for height measurement. The light for height measurement may include multiple components (e.g., red light, green light, etc.) having different wavelengths. For example, the light for height measurement may include white light. The light for height measurement that is output from the light source in the range sensor 113 may be radiated onto each substrate that is a reference sample through the beam splitter and the lens optical system. The components of the light for height measurement may be separated according to wavelengths by the lens optical system, and the focal length of the components of the light for height measurement may vary according to the wavelengths. The reflected light of the light for height measurement from each substrate is received by the detector through the beam splitter and a pinhole in a shield. The detector may detect the intensity of light that is incident through the pinhole. The intensity of the detected light may include height data used to measure the height of the reference sample. The detector may include a spectrometer, an imaging device such as a Charge-Coupled Device (CCD), and/or a camera. The light in a wavelength band that is focused on the surface of the reference sample among the components of the light for height measurement is measured by the detector at a relatively high intensity. Therefore, the height of the surface of the reference sample may be measured by detecting light in the wavelength band that is measured at a relatively high intensity.

In addition, a plurality of alignment marks 114 and 124 used for alignment of positions of the camera 60 are respectively installed/formed on the side surfaces of the first chuck 110 and the second chuck 120. The alignment marks 114 and 124 are installed/formed at specific/predetermined locations on the side surfaces of the first chuck 110 and the second chuck 120 so that the alignment marks 114 and 124 are positioned within a viewing angle (an imaging range) of the camera 60.

The driving unit 130 includes an XY stage 131, a Z stage 132, a theta stage 133, and a tilt stage 134. The XY stage 131 changes the location of the second chuck 120 in the horizontal directions (the X-axis direction and/or the Y-axis direction) relative to the first chuck 110.

The Z stage 132 changes the location of the second chuck 120 in the vertical direction (the Z-axis direction) relative to the first chuck 110. The theta stage 133 adjusts the tilt of the second chuck 120 in the horizontal plane (around the Z-axis) relative to the first chuck 110. For example, the theta stage 133 may adjust azimuth angle of the second chuck 120 with respect to the first chuck 110. The tilt stage 134 adjusts the tilt of the second chuck 120 in the vertical direction (around the X-axis or Y-axis) relative to the first chuck 110. For example, the tilt stage 134 may adjust polar angle of the second chuck 120 with respect to the first chuck 110. For example, each of the XY stage 131, the Z stage 132, the theta stage 133, and the tilt stage 134 may be a driving unit, e.g., a sub-driving unit, and the driving unit 130 forms a combined driving unit including each of the sub-driving units 131, 132, 133, and 134.

The measurement unit 20 includes a first light source 50a, a second light source 50b, and a first camera 60a to an eighth camera 60h. The first light source 50a, the second light source 50b, and the first camera 60a to the eighth camera 60h may be arranged on an annular member (e.g., an annular ring) 71 surrounding the first chuck 110 and the second chuck 120.

The annular member/ring 71 is movable in the vertical direction (the Z-axis direction) by the driving unit 72. The driving unit 72 moves the first light source 50a, the second light source 50b, and the first camera 60a to the eighth camera 60h between the measurement location, where the first light source 50a, the second light source 50b, and the first camera 60a to the eighth camera 60h are positioned around the second chuck 120 and/or the first chuck 110, e.g., at a substantially the same level as the first chuck 110 and the second chuck 120, and a retracted position/location, where the first light source 50a, the second light source 50b, and the first camera 60a to the eighth camera 60h are positioned/displaced below the second chuck 120. For example, the driving unit 72 may be a driver moving the annular ring 71 and/or the cameras 60a to 60h and the light sources 50a and 50b. For example, the driving unit 72 may be a ring driver.

The first light source 50a and the second light source 50b are positioned on the side of the second chuck 120 and/or the first chuck 110 and radiate light onto the region between the first chuck 110 and the second chuck 120. The first light source 50a and the second light source 50b are laser light sources for radiating, for example, blue light, and radiate/emit slit light with a specific/predetermined divergence angle in a horizontal direction, the slit light being radiated/emitted parallel to the wafer holding surfaces of the first chuck 110 and the second chuck 120. Moreover, to restrict the output from the light source 50, it is advantageous to set the slit width (the height in the vertical direction) of the slit light to be equal to or less than the gap between the first wafer W1 and the second wafer W2 (about 10 μm to about 100 μm) that are held in place by suction by/on the first chuck 110 and the second chuck 120.

In some embodiments, the first light source 50a and the second light source 50b radiate linearly polarized light (e.g., P-polarized light or S-polarized light). The first light source 50a and the second light source 50b are equipped with various filters 51, such as polarization filters that convert light into P-polarized light and/or S-polarized light, ND filters that adjust a light amount, and spatial filters that adjust the divergence angle of light. Such parameters are appropriately set based on the Brewster's angle or scattering characteristics of the surfaces of the wafers (the first wafer W1 and the second W2).

The first camera 60a to the eighth camera 60h are arranged on the opposite sides of the first light source 50a and the second light source 50b with the first chuck 110 and the second chuck 120 therebetween and capture images of the regions where light is radiated by/from the first light source 50a and the second light source 50b. The first camera 60a to the eighth camera 60h are arranged at regular angular intervals to surround half (180 degrees) of the periphery of the first chuck 110 and the second chuck 120, e.g., in a plan view. The first camera 60a to the eighth camera 60h are each an image sensor, such as a CCD or a CMOS, and capture images of the above mentioned regions in a specific/predetermined imaging cycle (e.g., a frequency of about 1 kHz).

Additionally, the structures of the bonding unit 10 and the measurement unit 20 are not limited to those described above. For example, the measurement unit 20 may include either at least nine or at most seven cameras 60. Alternatively, the measurement unit 20 may include a single light source 50. For example, the measurement unit 20 may include one or more light sources 50.

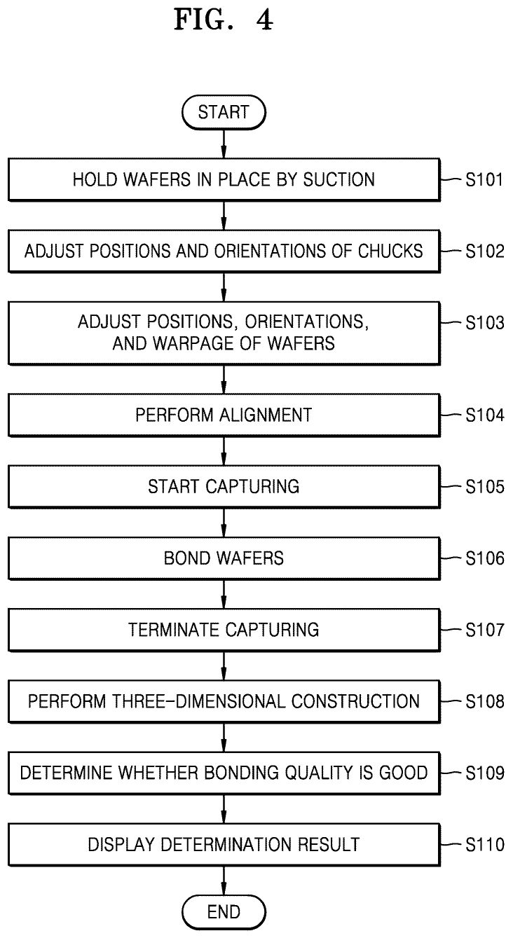

In the wafer bonding device 1 configured as described above, the bonding of the first wafer W1 and the second wafer W2 is measured and evaluated in situ. For example, by three-dimensionally reconstructing the image data obtained by capturing images of the first wafer W1 and the second wafer W2 in the bonding process by using the cameras 60, the bonding scene of the first wafer W1 and the second wafer W2 is restored as a three-dimensional model (three-dimensional image data). Based on the three-dimensional image data representing the bonding scene of the first wafer W1 and the second wafer W2, the bonding quality of the first wafer W1 and the second wafer W2 is determined. Hereinafter, the operation of the wafer bonding device 1 is described with reference to FIGS. 4 to 6.

FIG. 4 is a flowchart of a wafer bonding process of a wafer bonding device, according to an embodiment.

FIG. 4 is a flowchart showing a wafer bonding process performed by the wafer bonding device 1 in sequence. Additionally, the process shown in the flowchart of FIG. 4 is implemented as the controller 40 controls the operation of each unit of the wafer bonding device 1 or performs various computational operations.

According to an embodiment, the controller 40 may be implemented as hardware, firmware, software, or any combination thereof. For example, the controller 40 may include a computing device of a workstation computer, a desktop computer, a laptop, a tablet computer, or the like. The controller 40 may include a simple controller, a complex processor such as a microprocessor, a CPU, or a GPU, or a processor including software, dedicated hardware, or firmware. The controller 40 may be implemented using, for example, a general-purpose computer or application-specific hardware such as a Digital Signal Processor (DSP), a Field Programmable Gate Array (FPGA), and an Application-Specific Integrated Circuit (ASIC). The controller 40 may be implemented as instructions stored in a machine-readable medium that is readable and executable by one or more processors. Here, the machine-readable medium may include any mechanism configured to store and/or transmit information in a form readable by a machine (e.g., a computing device). For example, the machine-readable medium may include ROM, RAM, magnetic disk storage media, optical storage media, flash memory devices, electric, optical, acoustic, or other forms of radio signals (e.g., carrier waves, infrared signals, digital signals, etc.) and other arbitrary signals.

Operation S101 is described hereinafter.

First of all, the wafer bonding device 1 holds the first wafer W1 and the second wafer W2 in place by suction by using the first chuck 110 and the second chuck 120. For example, after radiating plasma onto the first wafer W1 and the second wafer W2 by using the plasma radiation unit 30, the wafer bonding device 1 transfers the first wafer W1 and the second wafer W2 to a position near the first chuck 110 and the second chuck 120 by using a transfer robot (not shown). The wafer bonding device 1 generates negative pressure on the wafer holding surfaces of the first chuck 110 and the second chuck 120 to hold the first wafer W1 and the second wafer W2 in place by suction by using the first chuck 110 and the second chuck 120.

In addition, while the first wafer W1 and the second wafer W2 are transferred to the bonding unit 10 from the plasma radiation unit 30, the light source 50 and the camera 60 wait at the retracted position below the first chuck 110 and the second chuck 120. Then, when the first wafer W1 and the second wafer W2 are held in place by suction by the first chuck 110 and the second chuck 120, the light source 50 and the camera 60 move from the retracted position below the first chuck 110 and the second chuck 120 to a measurement position around the first chuck 110 and the second chuck 120.

Operation S102 is described hereinafter.

The wafer bonding device 1 adjusts the positions and orientations of the first chuck 110 and the second chuck 120. For example, the wafer bonding device 1 detects the distance between the first chuck 110 and the second chuck 120 by primarily using a plurality of range sensors 113. The wafer bonding device 1 adjusts the distance between the first chuck 110 and the second chuck 120 or the tilt of the second chuck 120 relative to the first chuck 110 by controlling the Z stage 132 and the tilt stage 134 based on the output from the range sensors 113. In the present embodiment, the wafer bonding device 1 adjusts the positions and orientations of the first chuck 110 and the second chuck 120 to ensure that the distance between the first chuck 110 and the second chuck 120 or parallelism thereof falls within a specific allowable range.

Operation S103 is described hereinafter.

The wafer bonding device 1 adjusts the positions, orientations, and warpage of the first wafer W1 and the second wafer W2. For example, the wafer bonding device 1 first captures an image of the region between the first chuck 110 and the second chuck 120 by using the camera 60. The wafer bonding device 1 adjusts the distance between the first wafer W1 and the second wafer W2 or the tilt of the second wafer W2 relative to the first wafer W1 by controlling the Z stage 132 and the tilt stage 134 based on the image data that may be obtained by capturing images of the region with the camera 60. In the present embodiment, the wafer bonding device 1 adjusts the positions and orientations of the first wafer W1 and the second wafer W2 to ensure that the distance between the first wafer W1 and the second wafer W2 or parallelism thereof falls within a specific allowable range and the light from the light source 50 is appropriately incident to the camera 60. By adjusting the distance between the first wafer W and the second wafer W2 within the allowable range, the wafer bonding device 1 may accommodate wafers with different thicknesses.

In addition, the wafer bonding device 1 adjusts the suction retention force of the first chuck 110 and the second chuck 120 on a division region basis by controlling the control valve 15, which serves as a control unit, based on the image data obtained by capturing images of the region using the camera 60; thus, the warpage of the first wafer W1 and the second wafer W2 is adjusted. For example, the control valve 15 may be a suction adjuster for adjusting suction retention force of the first chuck 110 and/or the second chuck 120. For example, the wafer bonding device 1 may include a plurality of valves 15 to independently control suction retention forces of the first chuck 110 and the second chuck 120 from each other and/or to independently control suction retention forces of the respective division regions from each other. For example, when the first wafer W1 is bent downwards due to its own weight, the controller 40 relieves the warpage of the first wafer W1 by selectively increasing the suction retention force of the division region at the center of the first chuck 110.

Operation S104 is described hereinafter.

Next, the wafer bonding device 1 performs alignment of the first wafer W1 with the second wafer W2. For example, the wafer bonding device 1 first captures an image of the alignment marks of the first wafer W1 and the second wafer W2 by using the infrared cameras 112. The wafer bonding device 1 controls the XY stage 131 and the theta stage 133 based on the image data that may be obtained by capturing the image of the alignment marks by using the infrared cameras 112, thereby performing the alignment of the first wafer W1 with the second wafer W2.

Operation S105 is described hereinafter.

The wafer bonding device 1 initiates capturing images of the first wafer W1 and the second wafer W2 in the bonding process. For example, the wafer bonding device 1 initiates capturing a video of the first wafer W1 and the second wafer W2 in the bonding process by using the camera 60.

Operation S106 is described hereinafter.

The wafer bonding device 1 bonds the first wafer W1 to the second wafer W2. For example, the wafer bonding device 1 bonds the first wafer W1 to the second wafer W2 by controlling the bonding unit 10.

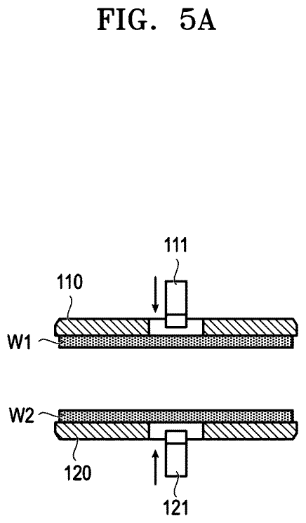

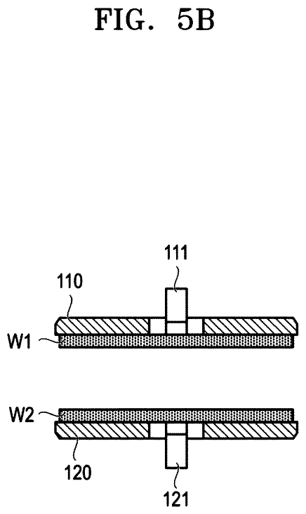

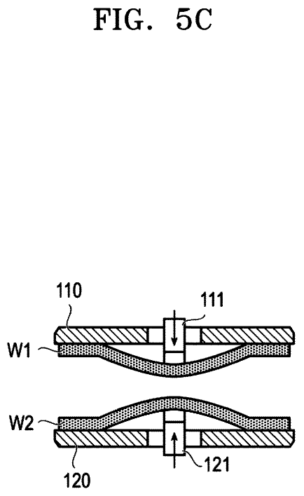

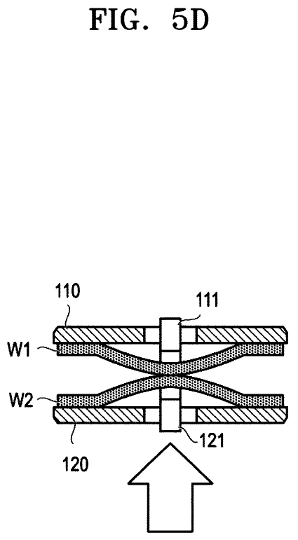

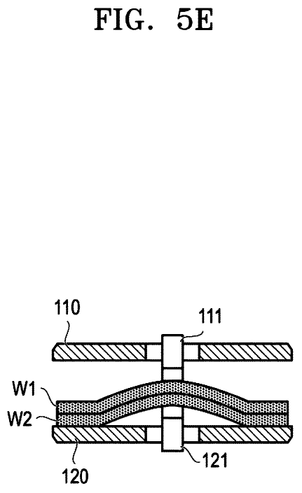

FIG. 5A illustrates an example in which a wafer bonding device bonds wafers, according to an embodiment. FIG. 5B is a diagram showing a subsequent process of FIG. 5A. FIG. 5C is a diagram showing a subsequent process of FIG. 5B. FIG. 5D is a diagram showing a subsequent process of FIG. 5C. FIG. 5E is a diagram showing a subsequent process of FIG. 5D. In describing operation S106 shown in FIG. 4, FIGS. 5A to 5E are referenced together.

FIGS. 5A to 5E are diagrams showing an example of the wafer bonding process. During the wafer bonding process, while the first wafer W1 and the second wafer W2 are held in place by suction by/on the first chuck 110 and the second chuck 120, the first pressing member 111 and the second pressing member 121 move towards the rear surfaces of the first wafer W1 and the second wafer W2 (see FIG. 5A). Then, the first pressing member 111 and the second pressing member 121 come into contact with the rear surfaces of the first wafer W1 and the second wafer W2, respectively (see FIG. 5B).

Next, the central portions of the first wafer W1 and the second wafer W2 are pressed by the first pressing member 111 and the second pressing member 121, and the first wafer W1 and the second wafer W2 are bent so that the central portions of the first wafer W1 and the second wafer W2 come close to each other (see FIG. 5C). The second chuck 120 elevates so that the central portion of the first wafer W1 contacts the central portion of the second wafer W2 (see FIG. 5D). Then, as the suction holding of the first wafer W1 by the first chuck 110 is released, the region where the first wafer W1 contacts the second wafer W2 expands from the central portion to the edge portion such that the first wafer W1 contacts the second wafer W2 (see FIG. 5E).

Operation S107 is described hereinafter.

Then, the wafer bonding device 1 terminates the capturing the video/images of the bonding process of the first wafer W1 and the second wafer W2. For example, the wafer bonding device 1 stops the capturing of the video with the camera 60. The image data obtained by capturing the images of the first wafer W1 and the second wafer W2 in the bonding process by using the camera 60 is stored in the storage unit of the controller 40.

Operation S108 is described hereinafter.

The wafer bonding device 1 three-dimensionally reconstructs the image data. For example, the wafer bonding device 1 generates three-dimensional image data, which represents the bonding scene of the first wafer W1 and the second wafer W2, by performing Radon transform on the image data that is obtained by capturing images of the first wafer W1 and the second wafer W2, which are being bonded to each other, by using the cameras 60. In addition, by repeatedly performing the Radon transform on consecutive pieces of image data at specific/predetermined time intervals (e.g., every 10 ms), the wafer bonding device 1 generates multiple pieces of three-dimensional image data (three-dimensional video data) representing the behavior/movements of the first wafer W1 and the second wafer W2 during the bonding process. The Radon transform is well-known technology, and the detailed description thereof is omitted.

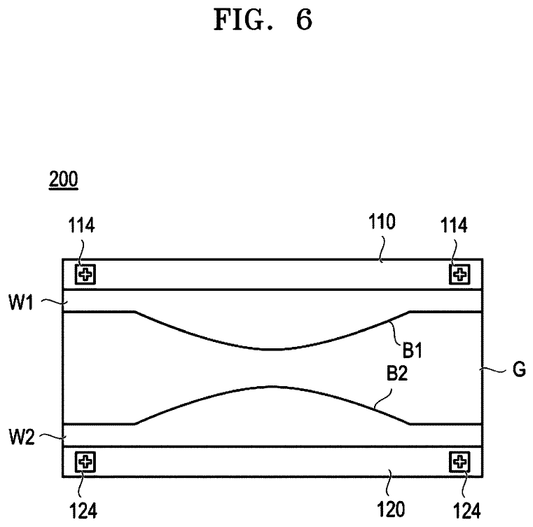

FIG. 6 illustrates an example of a captured image. In describing operation S108 shown in FIG. 4, FIG. 6 is referenced together.

FIG. 6 illustrates an example of a captured image 200. As shown in FIG. 6, the captured image 200 includes images of the side surfaces of the first chuck 110 and the second chuck 120 and images of the first wafer W1 and the second wafer W2. The images of the side surfaces of the first chuck 110 and the second chuck 120 include images of the alignment marks 114 and 124 that are used for aligning the cameras 60.

In the wafer bonding device 1 of the present embodiment, an image of a region G between the first wafer W1 and the second wafer W2 has a higher brightness than the images of the first chuck 110 and the second chuck 120 or the images of the first wafer W1 and the second wafer W2 due to the light emitted from the light source 50. Therefore, in the wafer bonding device 1 of the present embodiment, the captured image 200 clearly shows a boundary B1 between the first wafer W1 and the region G and a boundary B2 between the second wafer W2 and the region G, wherein the captured image 200 is based on the image data that may be obtained by capturing images of the region between the first chuck 110 and the second chuck 120.

In the wafer bonding device 1 of the present embodiment, eight pieces of image data, which may be obtained by simultaneously capturing images of the first wafer W1 and the second wafer W2 from different angles by using eight cameras 60, are three-dimensionally reconstructed, and thus, the three-dimensional image data (the three-dimensional model) representing the bonding scene of the first wafer W1 and the second wafer W2 is generated. In addition, as the three-dimensional image reconstruction is repeatedly performed on the consecutive image data at specific/predetermined time intervals (e.g., every 10 ms), three-dimensional video data representing the behaviors/movements of the first wafer W1 and the second wafer W2 during the bonding process of the first wafer W1 and the second wafer W2 (about 1 second) is generated.

Operation S109 is described hereinafter.

The wafer bonding device 1 determines the bonding quality of the first wafer W1 and the second wafer W2. For example, the wafer bonding device 1 determines the bonding quality of the first wafer W1 and the second wafer W2 by inputting the three-dimensional video data generated in operation S108 into a trained model that has learned the relationship between the three-dimensional video data representing the behaviors/movements of two wafers and the bonding quality of the two wafers.

Operation S110 is described hereinafter.

Then, the wafer bonding device 1 displays the result of determining the bonding quality on the display and terminates the bonding process. For example, the wafer bonding device 1 displays, on the display, the result of determining the bonding quality by using the trained model described in operation S109 together with a video based on the three-dimensional video data, and then terminates the bonding process.

As described above, according to the process shown in the flowchart of FIG. 4, the bonding process of the first wafer W1 and the second wafer W2 is captured by the cameras 60, and the three-dimensional video data representing the behaviors/movements of the first wafer W1 and the second wafer W2 during the bonding process thereof is generated. The bonding quality of the first wafer W1 and the second wafer W2 is determined based on the three-dimensional video data. For example, the bonding of the first wafer W1 and the second wafer W2 is measured and evaluated in situ.

In the embodiment described above, a determination as to whether the bonding quality of the first wafer W1 and the second wafer W2 is good is made using the trained model that has learned the relationship between the bonding quality of the wafers and the three-dimensional video data representing the behaviors/movements of the wafers. However, unlike the embodiment described above, by displaying the video based on the three-dimensional video data on the display, a determination as to whether the bonding quality of the first wafer W1 and the second wafer W2 is good may be made by operators.

In the embodiment described above, the three-dimensional image data representing the bonding scene of the first wafer W1 and the second wafer W2 is generated by three-dimensionally reconstructing the image data that may be obtained by capturing images of the region between the first chuck 110 and the second chuck 120 with the cameras 60. The bonding scene of the first wafer W1 and the second wafer W2 may be captured without performing the three-dimensional reconstruction in certain embodiments. For example, the captured images may be used to evaluate the bonding quality between the first wafer W1 and the second wafer W2 in certain embodiments.

A wafer bonding device according to the above mentioned certain embodiments includes a bonding unit, a light source, and cameras. The bonding unit bonds a first wafer to a second wafer while holding the first wafer and the second wafer in place by suction using a first chuck and a second chuck, which are arranged to face each other, and making the first wafer and the second wafer come close to each other in the state in which at least one of the first wafer and the second wafer is bent so that the central portions of the first wafer and the second wafer contact each other first and then, contact portion of the first wafer and the second wafer expand from the central portions to the edge portions of the first wafer and the second wafer. The light source is arranged on the sides of the first chuck and the second chuck and radiates light onto the region between the first chuck and the second chuck, and the cameras are arranged on the opposite side of the light source with the first chuck and the second chuck therebetween and capture images of the region irradiated with the light emitted from the light source.

In addition, except that the image data, which may be obtained by capturing images of the above mentioned region using the cameras, is not subject to the three-dimensional reconstruction, the structure of the wafer bonding device according to the present embodiment is the same as that of the wafer bonding device according to the embodiments described above, and thus, detailed descriptions of the present embodiment are omitted. In the wafer bonding device according to the present embodiment, a gap distribution in the unbonded portion between the first wafer and the second wafer (e.g., a region corresponding to the region G shown in FIG. 6) in the bonding scene of the first wafer and the second wafer, may be taken from image data that may be obtained by capturing images of the region between the first chuck and the second chuck using the cameras.

The inventive concept is not limited to the above embodiments and may be embodied in various forms within the scope of the claims.

For example, in the embodiments above, three-dimensional reconstruction is performed after the capturing of the bonding process of the two wafers is completed, and three-dimensional image data representing the bonding scene of the first wafer W1 and the second wafer W2 is generated. However, the timing for the three-dimensional reconstruction is not limited to after the completion of the capturing of the bonding process, and the three-dimensional reconstruction may also be performed simultaneously with the video capturing of the bonding process.

Also, in the above embodiments, a case is described in which both the first wafer W1 and the second wafer W2 are bent when pressed by the first pressing member 111 and the second pressing member 121 during the bonding of the first wafer W1 and the second wafer W2. However, the method whereby the central portions of the first wafer and the second wafer come close to each other is not limited to the above embodiment; instead, any one of the first wafer W1 and the second wafer W2 may be bent by pressing any one of the first wafer W1 and the second wafer W2 by using a pressing member. Alternatively, the central portion of the wafer holding surface of at least one of the first chuck and the second chuck may be convex, and the wafers may be bent while being held in place by suction along the convex central portion of the wafer holding surface of at least one of the first chuck and the second chuck.

In addition, in the embodiments described above, a case is described in which a blue laser light source emitting blue light is used as a light source. However, the light source is not limited to the blue laser light source, and other laser light sources having a central wavelength in a range from about 200 nm to about 800 nm may be used. When the central wavelength of the laser light source is less than about 200 nm, a vacuum environment is required, which is not advantageous. Also, when the central wavelength of the laser light source is higher than about 800 nm, general image sensors such as CCDs or CMOSs may not be usable, which is not advantageous. In addition, the light source is not limited to a laser light source, and a white light source may also be used as a light source. In this case, light of a desired wavelength may be selectively used by a wavelength selection filter, etc.

In addition, in the embodiments described above, a case is described in which slit light is radiated/emitted from the light source. However, the light from the light source is not limited to slit light and may have another shape, e.g., expanding in a vertical direction. Additionally, the light emitted from the light source may be light other than linearly polarized light (e.g., P-polarized light or S-polarized light).

Also, in the above embodiments, a case is described in which the first chuck 110 is equipped with the range sensors 113. However, wafer bonding devices 1 are not limited to multiple range sensors 113, and a single range sensor 113 may be installed on the first chuck 110. In this case, in operation S102, the parallelism of the first chuck 110 and the second chuck 120 may not be adjusted, and the distance between the first chuck 110 and the second chuck 120 may only be adjusted.

Also, in the embodiment described above, the first wafer W1 and the second wafer W2 are aligned in the horizontal direction by capturing images of the alignment marks using the infrared cameras 112. However, in addition to the alignment in the horizontal direction, the distance between the first wafer W1 and the second wafer W2 may be adjusted based on the focal position when the images of the alignment marks are captured by the infrared cameras 112.

The means and methods of performing various processes in the wafer bonding device 1 according to the above embodiments may be implemented by one of an exclusive hardware circuit and a programmed computer. The program may be provided via a computer-readable recording medium, such as a USB memory or DVD-ROM, or online through a network such as the Internet. In this case, programs recorded on the computer-readable recording medium are generally transmitted to and stored in a storage, such as an HDD. Also, the programs may be provided as single application software or incorporated into software of the wafer bonding device 1 as one function thereof.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various changes in form and details may be made therein without departing from the spirit and scope of the following claims.

What is claimed is:

1. A wafer bonding device comprising:
a bonding unit comprising a first chuck and a second chuck that are arranged to face each other;
a light source arranged on sides of the first chuck and the second chuck and configured to radiate light onto a region between the first chuck and the second chuck;
a plurality of cameras arranged on an opposite side of the light source with the first chuck and the second chuck therebetween and configured to capture images of a region irradiated with the light emitted from the light source; and
a 3D image generator configured to generate three-dimensional image data representing a bonding scene of a first wafer and a second wafer by three-dimensionally reconstructing image data that is obtained by capturing the images of the region by using the plurality of cameras during the bonding of the first wafer and the second wafer,
wherein the bonding unit is configured to bond the first wafer to the second wafer while holding the first wafer and the second wafer in place by suction by using the first chuck and the second chuck and making the first wafer and the second wafer come close to each other in a state in which at least one of the first wafer and the second wafer is bent so that central portions of the first wafer and the second wafer contact each other.

2. The wafer bonding device of claim 1, wherein each of the plurality of cameras is configured to consecutively capture images of the region in a predetermined imaging cycle, and
the 3D image generator is further configured to generate pieces of the three-dimensional image data representing behaviors of the first wafer and the second wafer during a bonding process of the first wafer and the second wafer, based on image data that is consecutive at predetermined time intervals.

3. The wafer bonding device of claim 1, wherein the number of cameras is greater than the number of light sources.

4. The wafer bonding device of claim 1, further comprising:
a first driving unit configured to make the first chuck and the second chuck come close to each other; and
a controller configured to adjust a distance between the first wafer and the second wafer by controlling the first driving unit based on the image data that is obtained by capturing the images of the region by using the plurality of cameras.

5. The wafer bonding device of claim 4, further comprising:
a second driving unit configured to change a tilt of at least one of the first chuck and the second chuck,
wherein the controller is configured to adjust a tilt of at least one of the first wafer and the second wafer by controlling the second driving unit based on the image data that is obtained by capturing the images of the region by using the plurality of cameras.

6. The wafer bonding device of claim 5, further comprising:
a suction adjuster configured to adjust suction retention force of at least one of the first chuck and the second chuck,
wherein the controller is configured to adjust a tilt of at least one of the first wafer and the second wafer by controlling the first driving unit and the second driving unit based on the image data obtained by capturing the images of the region by using the plurality of cameras.

7. The wafer bonding device of claim 1, further comprising a third driving unit configured to move the light source and the plurality of cameras between a measurement position, where the light source and the plurality of cameras are arranged around the first chuck and the second chuck, and a retracted position, where the light source and the plurality of cameras are displaced from the measurement position.

8. The wafer bonding device of claim 1, wherein the light source is configured to radiate linearly polarized light.

9. The wafer bonding device of claim 1, wherein the light source is configured to adjust at least one of a divergence angle and amount of light.

10. The wafer bonding device of claim 1, wherein the light source comprises a laser light source with a central wavelength in a range from 200 nm to 800 nm.

11. A wafer bonding device comprising:
a bonding unit comprising a first chuck and a second chuck that are arranged to face each other;
a light source arranged on sides of the first chuck and the second chuck and configured to radiate light onto a region between the first chuck and the second chuck;
a plurality of cameras arranged on an opposite side of the light source with the first chuck and the second chuck therebetween and configured to capture images of a region irradiated with the light emitted from the light source; and
a 3D image generator configured to generate three-dimensional image data representing a bonding scene of a first wafer and a second wafer by three-dimensionally reconstructing image data that is obtained by capturing the images of the region by using the plurality of cameras during the bonding of the first wafer and the second wafer to each other,
wherein the bonding unit is configured to bond the first wafer to the second wafer while holding the first wafer and the second wafer in place by suction by using the first chuck and the second chuck and making the first wafer and the second wafer come close to each other in a state in which at least one of the first wafer and the second wafer is bent so that central portions of the first wafer and the second wafer contact each other,
each of the plurality of cameras is configured to consecutively capture images of the region in a predetermined imaging cycle,
the 3D image generator is further configured to generate pieces of the three-dimensional image data representing behaviors of the first wafer and the second wafer during the bonding of the first wafer and the second wafer, based on image data that is consecutive at predetermined time intervals, and
the number of cameras is greater than the number of light sources.

12. The wafer bonding device of claim 11, further comprising an infrared camera that emits infrared light,
wherein the infrared camera is configured to capture an image of an alignment mark of each of the first wafer and the second wafer.

13. The wafer bonding device of claim 11, further comprising a range sensor,
wherein the range sensor is configured to detect a distance between the first chuck and the second chuck.

14. The wafer bonding device of claim 11, further comprising a plasma radiation unit, wherein the plasma radiation unit is arranged separately from the bonding unit and configured to radiate plasma onto the first wafer and the second wafer before the first wafer and the second wafer are suctioned and held in place by the first chuck and the second chuck.

15. The wafer bonding device of claim 11, further comprising:
a first driving unit configured to make the first chuck and the second chuck come close to each other; and
a controller configured to adjust a distance between the first wafer and the second wafer by controlling the first driving unit based on the image data that is obtained by capturing images of the region by using the plurality of cameras.

16. The wafer bonding device of claim 15, further comprising:
a second driving unit configured to change a tilt of at least one of the first chuck and the second chuck; and
a suction adjuster configured to adjust suction retention force of at least one of the first chuck and the second chuck,
wherein the controller is configured to adjust a tilt of at least one of the first wafer and the second wafer by controlling the first driving unit and the second driving unit based on the image data obtained by capturing images of the region by using the plurality of cameras.

17. The wafer bonding device of claim 11, further comprising a third driving unit configured to move the light source and the plurality of cameras between a measurement position, where the light source and the plurality of cameras are arranged around the first chuck and the second chuck, and a retracted position, where the light source and the plurality of cameras are displaced from the measurement position.

18. The wafer bonding device of claim 11, wherein the light source is configured to radiate a polarized light and adjust at least one of a divergence angle and amount of light.

19. A wafer bonding device comprising:
a bonding unit comprising a first chuck and a second chuck that are arranged to face each other;
a light source arranged on sides of the first chuck and the second chuck and configured to radiate light onto a region between the first chuck and the second chuck;
a plurality of cameras arranged on an opposite side of the light source with the first chuck and the second chuck therebetween and configured to capture images of a region irradiated with the light emitted from the light source;
a 3D image generator configured to generate three-dimensional image data representing a bonding scene of a first wafer and a second wafer by three-dimensionally reconstructing image data that is obtained by capturing the images of the region by using the plurality of cameras during the bonding of the first wafer and the second wafer to each other;
an infrared camera that emits infrared light; and
a range sensor configured to detect a distance between the first chuck and the second chuck,
wherein the bonding unit is configured to bond the first wafer to the second wafer while holding the first wafer and the second wafer in place by suction on the first chuck and the second chuck respectively and making the first wafer and the second wafer come close to each other in a state in which at least one of the first wafer and the second wafer is bent so that central portions of the first wafer and the second wafer contact each other first and then edge portions of the first wafer and the second wafer contact each other,
each of the plurality of cameras is configured to consecutively capture images of the region in a predetermined imaging cycle,
the infrared camera is configured to capture an image of an alignment mark of each of the first wafer and the second wafer,
the 3D image generator is further configured to generate pieces of the three-dimensional image data representing behaviors of the first wafer and the second wafer during the bonding of the first wafer and the second wafer, based on image data that is consecutive at predetermined time intervals, and
the number of cameras is greater than the number of light sources.

20. The wafer bonding device of claim 19, further comprising:
a first driving unit configured to make the first chuck and the second chuck come close to each other;
a second driving unit configured to change a tilt of at least one of the first chuck and the second chuck;
a suction adjuster configured to adjust suction retention force of at least one of the first chuck and the second chuck; and
a controller configured to adjust a distance between the first wafer and the second wafer by controlling the first driving unit and a tilt of at least one of the first wafer and the second wafer by controlling the first driving unit and the second driving unit based on the image data obtained by capturing images of the region by using the plurality of cameras.
